(19) United States
(12) Patent Application Publication
(10) Pub. No.: US 2021/0359483 A1
(43) Pub. Date: Nov. 18, 2021

(54) VISIBLE AND TUNABLE RING CAVITY LASER SOURCE

(71) Applicant: NATIONAL UNIVERSITY OF SINGAPORE, Singapore (SG)

(72) Inventors: Henrique GUIMARAES ROSA, Singapore (SG); Antonio Helio De CASTRO NETO, Singapore (SG)

(73) Assignee: NATIONAL UNIVERSITY OF SINGAPORE, Singapore (SG)

(21) Appl. No.: 17/319,318

(22) Filed: May 13, 2021

(30) Foreign Application Priority Data
May 13, 2020 (SG) 10202004444W

(51) Int. Cl. H01S 3/067; H01S 3/094

(52) U.S. Cl. CPC H01S 3/06716; H01S 3/0675; H01S 3/06791; H01S 3/094003

(57) ABSTRACT

A ring cavity laser source, a tunable ring cavity laser source and a method of fabricating a ring cavity laser source. The fiber ring cavity laser source comprises a fiber pigtailed pump laser; a fiber-based gain medium; a fiber-based circulator; a fiber-based coupler, wherein an input fiber port of the fiber-based coupler is coupled to a first end of the fiber-based gain medium, a first output fiber port of the fiber-based coupler is coupled to a first fiber port of the fiber-based circulator, and a second output fiber port of the fiber-based coupler is configured for extracting a laser output of the fiber ring cavity laser source; a fiber-based reflector coupled to a second fiber port of the fiber-based circulator; and a fiber-based combiner, wherein a first input fiber port of the fiber-based combiner is coupled to the fiber pigtailed pump laser, a second input fiber port of the fiber-based combiner is coupled to a third fiber port of the fiber-based circulator, and an output fiber port of the fiber-based combiner is coupled to a second end of the fiber-based gain medium; wherein the fiber-based reflector is configured for wavelength tuning of the laser output.

### CROSS-REFERENCE TO RELATED APPLICATION

This application claims the benefit of priority of Singapore Patent Application No. 10202004444W filed on May 13, 2020, the content of which is incorporated herein by reference in its entirety for all purposes.

### TECHNICAL FIELD

This invention relates broadly to a ring cavity laser source, a tunable ring cavity laser source and a method of fabricating a ring cavity laser source, in particular to a tunable ring cavity laser source, and more particularly to a visible and tunable rare-earth-doped fluoride fiber and silica fiber ring cavity laser source.

### BACKGROUND

Any mention and/or discussion of prior art throughout the specification should not be considered, in any way, as an admission that this prior art is well known or forms part of common general knowledge in the field.

H. Okamoto et al., “Visible—NIR tunable Pr3+-doped fiber laser pumped by a GaN laser diode”, Optics Express 17, 20227-20232 (2009), describes the setup and functioning of a tunable visible fiber laser with reasonable output power across all wavelengths. This laser was build-up on a blue laser diode pump and open-air optics elements for tunability, which may be versatile for principle demonstration but is not suitable for industrial and commercial applications.

On the other hand, tunable laser sources that are currently commercially available have, at some stage of their functioning, open-air optics responsible or as part of the tuning mechanism. Such assemblies require highly specialized manpower for operation, tuning, and realignment, and are prone to misalignment and failure depending on the application environment conditions.

Embodiments of the present invention seek to address one or more of the above-mentioned problems.

### SUMMARY

In accordance with a first aspect of the present invention there is provided a fiber ring cavity laser source comprising a fiber pigtailed pump laser; a fiber-based gain medium; a fiber-based circulator; a fiber-based coupler, wherein an input fiber port of the fiber-based coupler is coupled to a first end of the fiber-based gain medium, a first output fiber port of the fiber-based coupler is coupled to a first fiber port of the fiber-based circulator, and a second output fiber port of the fiber-based coupler is configured for extracting a laser output of the fiber ring cavity laser source; a fiber-based reflector coupled to a second fiber port of the fiber-based circulator; and a fiber-based combiner, wherein a first input fiber port of the fiber-based combiner is coupled to the fiber pigtailed pump laser, a second input fiber port of the fiber-based combiner is coupled to a third fiber port of the fiber-based circulator, and an output fiber port of the fiber-based combiner is coupled to a second end of the fiber-based gain medium; wherein the fiber-based reflector is configured for wavelength tuning of the laser output.

In accordance with a second aspect of the present invention there is provided a tunable ring cavity laser source comprising a ring cavity structure; a fiber-based circulator coupled in an optical path of the ring cavity structure; a fiber-based reflector coupled to a fiber port of the circulator; and a tuning component for the fiber-based reflector for wavelength tuning an output laser signal of the ring cavity laser source.

In accordance with a third aspect of the present invention there is provided a method of fabricating a ring cavity laser source, the method comprising the steps of coupling a first output fiber port of a fiber-based coupler to a first fiber port of a fiber-based circulator; coupling an input fiber port of the fiber-based coupler to a first end of a fiber-based gain medium; coupling a fiber-based reflector to a second port of the fiber-based circulator; coupling a first input fiber port of a fiber-based combiner to the fiber pigtailed pump laser; coupling a second input fiber port of the fiber-based combiner to a third port of the fiber-based circulator; coupling an output fiber port of the fiber-based combiner to a second end of the fiber-based gain medium; and configuring the fiber-based reflector for wavelength tuning of a laser output at a second output fiber port of the fiber-based coupler.

### BRIEF DESCRIPTION OF THE DRAWINGS

The invention will be better understood with reference to the detailed description when considered in conjunction with the non-limiting examples and the accompanying drawings, in which:

FIG. 1 shows the design of a laser ring cavity according to an example embodiment.

FIG. 2 shows a graph of Amplified Spontaneous Emission of the Praseodymium-doped fluoride fiber of the laser ring cavity of FIG. 1 under blue laser pumping.

FIG. 3 shows a schematic drawing illustrating the operation of wavelength tuning according to an example embodiment.

FIG. 4 shows a flowchart illustrating a method of fabricating a ring cavity laser source, according to an example embodiment

### DETAILED DESCRIPTION

The laser source according to an example embodiment described herein has two main capabilities: it emits visible radiation, which means its output light ranges from blue to red colors in the electromagnetic spectrum, and is tunable, which means the output wavelength is capable of being controlled and changed actively during the laser operation. In the example embodiment, the laser cavity is formed entirely by optical fiber components, with fiber-to-fiber coupling, which can provide the laser with one or more of a series of advantages, such as low-loss configuration setup, alignment-free and turn-key operation, small foot-print, and fully customizable configuration for output beam (central wavelength, wavelength range, average power, and CW or pulsed operation). The laser according to the example embodiment can be of particular interest for applications including, but not limited to, in material science and life sciences, where visible wavelength tunability with high reliability and narrow bandwidth are required. Furthermore, industrial applications of the example embodiment include, but are not limited to, in the semiconductor industry and in quality inspection where on-site and field inspection of optical properties in as-produced item are demanded.

Additionally or alternatively, a method and system for tunability in visible laser sources is provided according to an example embodiment described herein, for deployment in various ring cavity lasers.

The tunable fiber laser source and/or the method and system for tunability in visible laser sources according to example embodiments can be custom-designed towards many different applications, where different specifications and parameters may be required and tailored, such as small or large foot-print, central wavelength and tunability range, beam parameters, output power and pulse-duration, among others.

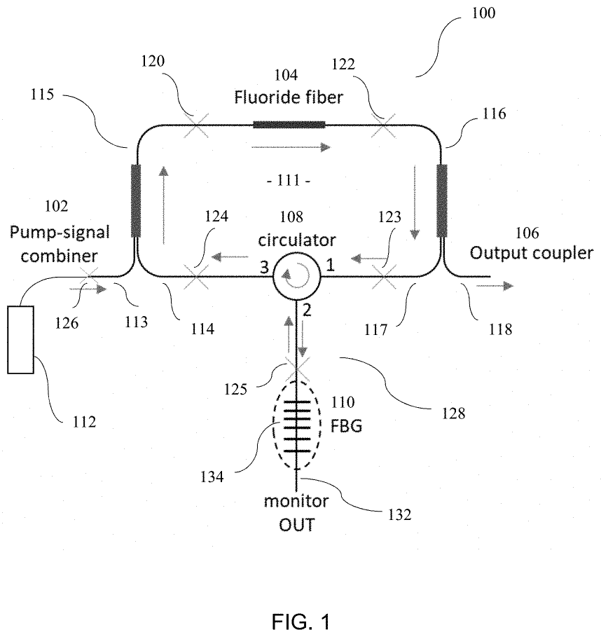

FIG. 1 shows the design of a fiber ring cavity laser source 100 according to an example embodiment. The fiber components depicted include pump-signal combiner 102, fluoride fiber 104, output coupler 106, circulator 108, and fiber Bragg grating reflector 110.

Because the fiber ring cavity laser source 100 comprises a closed-loop 111 of optical fibers with fiber-to-fiber coupling, a mirror-less laser cavity is advantageously provided according to the example embodiment, which can provide several advantages over linear configurations and resonators which use some type of open-optics components, including, but not limited to alignment-free, improved optical stability and less susceptibility to environment (thermal and mechanical) fluctuations.

In the example embodiment, the generation of visible laser light with the fiber ring cavity laser source 100 design comprising in its formation 100% optical fibers and optical fiber components, is characterized in that it is preferably free from light propagation through air at any component during the laser pumping and emission. Specifically, the fiber components are, the fiber pigtailed pump laser 112, in this example embodiment blue wavelength; the optical fiber pump-signal combiner 102, which includes pump/signal/common fiber ports 113-115; the optical fiber gain medium, in this example embodiment the Praseodymium-doped fluoride optical fiber 104, pumped with the blue laser light from the fiber pigtailed pump laser 112 and capable of emitting laser light at blue, green, yellow, orange, red and infrared wavelengths; the output coupler 106, which includes optical fiber signal/tap fiber ports 116-118; the circulator 108, here an optical fiber 3-port circulator; and the fiber Bragg grating reflector 110. In one non-limiting example, fiber pigtailed pump laser 112 can be a GaN (gallium nitride) high-power semiconductor laser(s).

Accordingly, in the example embodiment the optical fiber gain medium is directly pumped by the fiber pigtailed (also sometimes referred to as fiber-integrated or fiber coupled) blue pump laser 112, during which process a flux of photons of higher energy will cause an electronic population inversion in the gain medium. As a result, photons of lower energy will be emitted during the relaxation process following pump excitation. Such lower energy photons are the laser light generated by the fiber ring cavity laser source 100 according to the example embodiment at fiber port 118 of the output coupler 106.

In the example embodiment, the gain medium is the Praseodymium-doped fluoride fiber 104, which is made of a fluoride glass, a type of soft glass with different properties if compared to conventional silica fiber, as will be appreciated by a person skilled in the art. It is noted that the output wavelength of the fiber ring cavity laser source according to example embodiments depends on the glass properties of gain medium fiber and the specific pump laser wavelength selected. For example, an embodiment with a pump laser of 980 nm and an Erbium-doped silica fiber would emit in the 1550 nm (infrared), whereas an embodiment with a pump laser of 970 nm and an Ytterbium-doped silica fiber would emit in the 1060 nm (infrared).

As mentioned above, the fiber ring cavity laser source 100 according to the example embodiment is advantageously comprised, in full, by optical fibers and optical fiber components, i.e. is free from light propagation though air.

The Praseodymium-doped fluoride optical fiber 104 (i.e. a fluoride soft glass type) is fiber-to-fiber coupled to the remaining optical fiber components made with conventional silica fibers in the example embodiment via mechanical or thermal splicing methods, such that light propagation from one fiber to another preferably achieves minimal losses. These processes can provide splices 120, 122 which can achieve losses as low as 0.01 dB. On the other hand, conventional arc discharge splicing method typically result in higher losses when splicing fibers with melting temperatures that are too different. The remaining fiber-to-fiber couplings are between the same/similar type(s) of optical fiber in the example embodiment, and hence may be formed using conventional arc discharge splices 123-126.

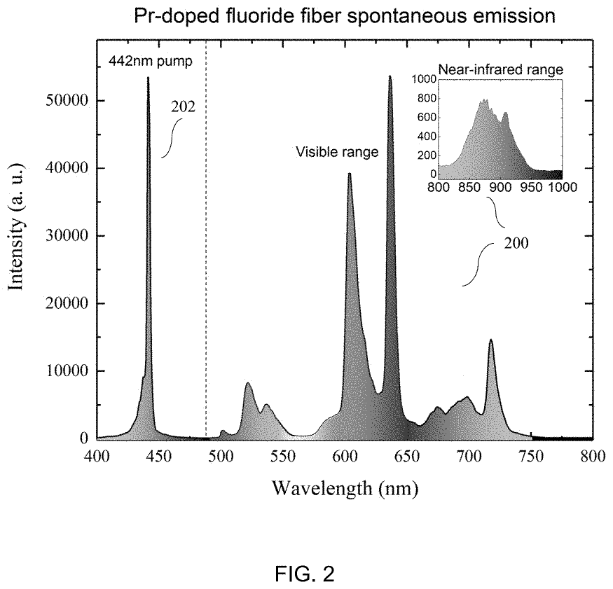

In the example embodiment, when the Praseodymium ions present in the Praseodymium-doped fluoride optical fiber 104 are pumped by blue light, electronic population inversion will occur, and during the relaxation process visible and infrared light are emitted via spontaneous emission, constituting the spectral range for laser emission of the fiber ring cavity laser source 100, as shown in FIG. 2. Each spectral range is a potential region for laser emission/operation, depending upon the spectral range and the specification of all other fiber components selected for the laser cavity implementation. It is noted that blue wavelengths emission other than 442 nm (from the fiber pigtailed blue pump laser in this example embodiment) can be considered as part of the output spectral range, because the conversion from 442 nm to another wavelength will occur at the fiber gain medium. For example, the 442 nm pump can be converted to 465-475 nm in the fluoride fiber, therefore the output can also be tuned in that range in the example embodiment.

Specifically, FIG. 2 shows a graph of Amplified Spontaneous Emission 200 of the Praseodymium-doped fluoride fiber 104 under blue laser pumping 202, showing the potential for ultra-broadband visible and infrared fiber laser emission.

Returning to FIG. 1, in the example embodiment the pump laser light is launched into the closed loop 111 of the fiber ring cavity laser source 100 via an optical fiber component referred to herein as the pump-signal combiner 102. This component has one input pump fiber port 113, one signal input fiber port 114, and one common fiber port 115 in which pump and signal propagate simultaneously. Since the pump-signal combiner 102 is made entirely of optical fibers, it advantageously does not require further alignments once it is spliced in the closed loop 111. Low loss all-fiber pump-signal combiners for visible wavelengths are commercially available such as, but not limited to, the WDM-1-450532-S-B-Q-1, SR19238 blue-green pump/signal combiner from Advanced Fiber Resources (China).

On the other hand, in the example embodiment the generated laser light is output via an all-fiber component referred to herein as the signal output coupler 106. This component has one input fiber port 116, and two output fiber ports 117, 118. The total input power from fiber port 116 is split between the output fiber ports 117 118, with the higher ratio being returned to the laser resonator via output fiber port 117, and the lower ratio propagating in the laser output fiber port 118. Low loss all-fiber output couplers are commercially available, with insertion loss as low as 0.2 dB, such as, but not limited to, the MC-1-532-10 green wavelength signal splitter from Advanced Fiber Resources (China).

An all-fiber isolator (not shown) is an optional component, which can be used in the fiber ring cavity laser source 100 to ensure uni-directional propagation of light.

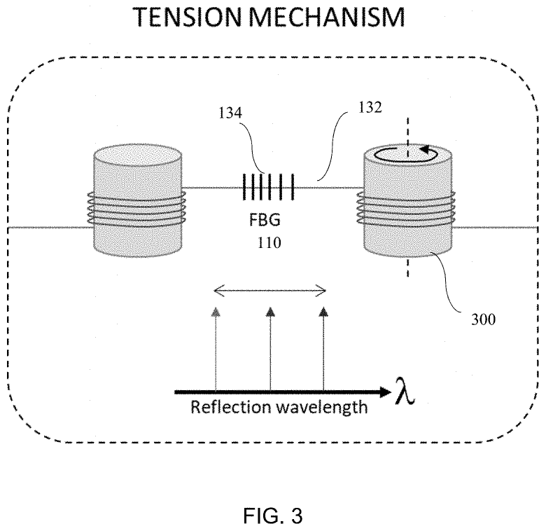

The fiber ring cavity laser source 100 shown in FIG. 1 also includes a tuning mechanism according to an example embodiment, responsible for the wavelength tunability of the generated and amplified laser light. A tuning arm 128 is formed by the use of two all-fiber components in the example embodiment: The all-fiber optical circulator 108, which is a fiber component with the three fiber ports 1-3, in which light propagates from fiber port 1 to fiber port 2, from fiber port 2 to fiber port 3, and from fiber port 3 to fiber port 1. Light propagating in the reversed direction is blocked, as will be appreciated by a person skilled in the art. Circulators as in the embodiment example are commercially available such as, but not limited to, the VCIR-3-532-S-L-10-FA green wavelength circulator from Ascentta (USA). In the presence of a reflecting optical component, in the form of the Fiber Bragg Grating (FBG) 110 at fiber port 2 in the example embodiment, light propagating from fiber port 1 to fiber port 2 is reflected back and therefore will propagate from fiber port 2 to fiber port 3. If the reflecting optical component is capable of reflection wavelength tunability, this tuning arm 128 advantageously functions as a tuning mechanism, for selecting the light to be reflected back to the laser cavity. As mentioned, in the example embodiment the reflecting optical component is realized through the use of the FBG 110. As will be appreciated by a person skilled in the art, FBGs are optical fibers, here fiber 132, with a Bragg grating, here Bragg grating 134, inscribed somewhere along their lengths, and once tensile or compressive forces are applied to the fiber 132, the periodicity of the grating 134 changes, consequently changing the reflected wavelength, as shown in FIG. 3 and as will be described in more detail below for the example embodiment. The combination of optical circulator 108 and FBG 110 forms the all-fiber tuning mechanism according to the example embodiment.

FIG. 3 shows a schematic drawing illustrating the operation of wavelength tuning according to the example embodiment, in particular the tension mechanism applied to the FBG 110, responsible for the tunability of the central emission wavelength. Once the fiber 132 is tensioned, the periodicity of the Bragg grating 134 changes, causing the reflected wavelength to change accordingly. In this example embodiment, the tensioning mechanism is implemented using one or more spool cylinders e.g. 300, onto which a portion of the fiber 132 is wound. In one operation mode, the spool cylinders e.g. 300 are used to pre-tension the fiber 132 into a default state, in which the Bragg grating 134 is configured to reflect at the desired center wavelength of the laser cavity. As will be appreciated by a person skilled in the art, variation of the tension by rotation of the cylinders e.g. 300 clock-wise or counter clock-wise can then be used to vary the tension around the default state, resulting in changes in the period of the Bragg grating 134, which in turn changes the reflection wavelength around the center wavelength. However, it will be appreciated that the tensioning and/or a compression mechanism can be implemented in different ways in different example embodiments, such as, but not limited to, using translation stages, and/or using tension and/or compression cells mechanisms.

As will be appreciated by a person skilled in the art, every optical fiber component has its own operation bandwidth and, as a consequence, each component used in the fiber ring cavity laser source 100 acts as a bandwidth limiter. Even though the gain medium, Praseodymium-doped fluoride optical fiber 104 in the example embodiment, is capable of operating in a broad range of wavelengths, the fiber ring cavity laser source 100 will have its operation according to the bandwidth of the optical fiber components used in its setup. The central wavelength and the tunability of the fiber ring cavity laser source 100 around the central wavelength (can be in blue, green, yellow, orange, red or near-infrared according to the operation bandwidth of the pump-signal combiner 102, output coupler 106, and circulator 108) will be determined by the FBG 110 properties (central wavelength, reflectivity bandwidth and ratio, fiber Young modulus).

As described herein, embodiments of the present invention can provide a visible tunable fiber laser source that is alignment-free, turn-key operational, tunable, and custom-designed towards a required application, including being fully customizable in terms of laser specification (wavelength, tunability range, output power, mode of operation). It is noted that the central wavelength and tunability range control has been described in detail above in relation to an example embodiment. Other properties, such as power, polarization, and others, can be controlled externally to the laser resonator, as will be appreciated by a person skilled in the art.

Embodiments of the present invention can have one or more of the following features and associated benefits/advantages:

Primary visible laser source with tunability: There are no commercially available primary laser sources capable of, simultaneously, emitting green and/or red light and being tunable. This is in contrast to existing sources such as a Titanium: Sapphire laser, which is down-limited to red light generation.

All optical components used in the laser cavity design according to an example embodiment are fiber-based components, i.e. all-optical design: This brings many benefits to the laser cavity design according to an example embodiment, such as low-loss components, long-term mechanical and thermal stability, maintenance-free and realignment-free.

In an example embodiment, a fiber ring cavity laser source is provided comprising a fiber pigtailed pump laser; a fiber-based gain medium; a fiber-based circulator; a fiber-based coupler, wherein an input fiber port of the fiber-based coupler is coupled to a first end of the fiber-based gain medium, a first output fiber port of the fiber-based coupler is coupled to a first fiber port of the fiber-based circulator, and a second output fiber port of the fiber-based coupler is configured for extracting a laser output of the fiber ring cavity laser source; a fiber-based reflector coupled to a second fiber port of the fiber-based circulator; and a fiber-based combiner, wherein a first input fiber port of the fiber-based combiner is coupled to the fiber pigtailed pump laser, a second input fiber port of the fiber-based combiner is coupled to a third fiber port of the fiber-based circulator, and an output fiber port of the fiber-based combiner is coupled to a second end of the fiber-based gain medium; wherein the fiber-based reflector is configured for wavelength tuning of the laser output.

The fiber-based gain medium may be configured for amplified spontaneous emission based on a pump signal from the fiber-based pump laser.

The fiber-based gain medium may comprise a Fluoride.

The fiber-based gain medium may comprise a rare-earth doped Fluoride.

The fiber-based gain medium may comprise Praseodymium-doped Fluoride.

The fiber-based gain medium may be configured for generating an emission having a spectral range.

The spectral range may comprise visible light.

The spectral range may comprise blue to red visible light.

The spectral range may comprise near-infrared light.

The spectral range may comprise visible light and near-infrared light.

The spectral range may comprise blue to near-infrared light.

The fiber-based reflector may comprise a Fiber Bragg Grating.

The fiber ring cavity laser may comprise a tuning component for tensioning and/or compressing the Fiber Bragg Grating.

At least the fiber-based circulator, the fiber-based coupler, and the fiber-based combiner may be configured for an operation range of the laser output.

In one embodiment a tunable ring cavity laser source is provided comprising a ring cavity structure; a fiber-based circulator coupled in an optical path of the ring cavity structure; a fiber-based reflector coupled to a fiber port of the circulator; and a tuning component for the fiber-based reflector for wavelength tuning an output laser signal of the ring cavity laser source.

The fiber-based reflector may comprise a fiber Bragg grating.

The tuning component may be configured for tensioning and/or compressing the fiber Bragg grating for effecting the wavelength tuning.

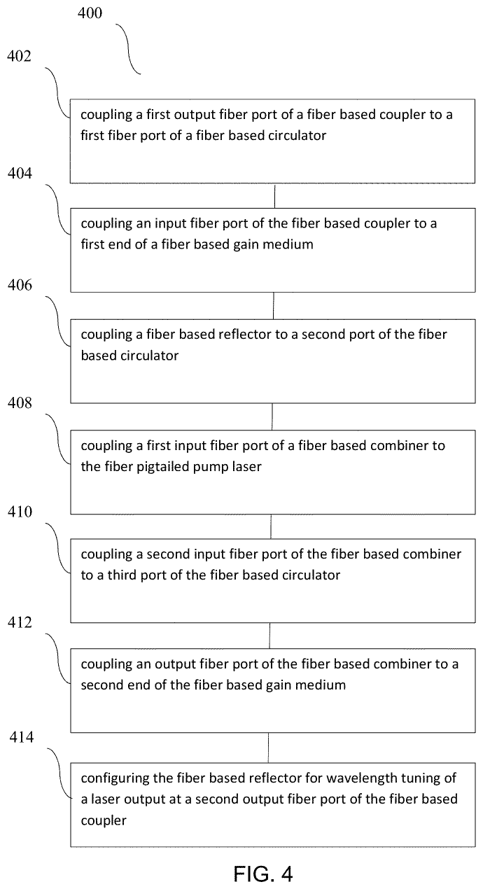

FIG. 4 shows a flowchart 400 illustrating a method of fabricating a ring cavity laser source, according to an example embodiment. At step 402, a first output fiber port of a fiber-based coupler is coupled to a first fiber port of a fiber-based circulator. At step 404, an input fiber port of the fiber-based coupler is coupled to a first end of a fiber-based gain medium. At step 406, a fiber-based reflector is coupled to a second port of the fiber-based circulator. At step 408, a first input fiber port of a fiber-based combiner is coupled to the fiber pigtailed pump laser. At step 410, a second input fiber port of the fiber-based combiner is coupled to a third port of the fiber-based circulator. At step 412, an output fiber port of the fiber-based combiner is coupled to a second end of the fiber-based gain medium. At step 414, the fiber-based reflector is configured for wavelength tuning of a laser output at a second output fiber port of the fiber-based coupler.

The fiber-based reflector may comprise a fiber Bragg grating.

The method may comprise configuring the fiber Bragg grating for tensioning and/or compressing for effecting the wavelength tuning.

The above description of illustrated embodiments of the systems and methods is not intended to be exhaustive or to limit the systems and methods to the precise forms disclosed. While specific embodiments of, and examples for, the systems components and methods are described herein for illustrative purposes, various equivalent modifications are possible within the scope of the systems, components and methods, as those skilled in the relevant art will recognize. The teachings of the systems and methods provided herein can be applied to other processing systems and methods, not only for the systems and methods described above.

The elements and acts of the various embodiments described above can be combined to provide further embodiments. These and other changes can be made to the systems and methods in light of the above detailed description.

In general, in the following claims, the terms used should not be construed to limit the systems and methods to the specific embodiments disclosed in the specification and the claims, but should be construed to include all processing systems that operate under the claims. Accordingly, the systems and methods are not limited by the disclosure, but instead the scope of the systems and methods is to be determined entirely by the claims.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

What is claimed is:

1. A fiber ring cavity laser source comprising:
a fiber pigtailed pump laser;
a fiber-based gain medium;
a fiber-based circulator;
a fiber-based coupler, wherein an input fiber port of the fiber-based coupler is coupled to a first end of the fiber-based gain medium, a first output fiber port of the fiber-based coupler is coupled to a first fiber port of the fiber-based circulator, and a second output fiber port of the fiber-based coupler is configured for extracting a laser output of the fiber ring cavity laser source;
a fiber-based reflector coupled to a second fiber port of the fiber-based circulator; and
a fiber-based combiner, wherein a first input fiber port of the fiber-based combiner is coupled to the fiber pigtailed pump laser, a second input fiber port of the fiber-based combiner is coupled to a third fiber port of the fiber-based circulator, and an output fiber port of the fiber-based combiner is coupled to a second end of the fiber-based gain medium;
wherein the fiber-based reflector is configured for wavelength tuning of the laser output.

2. The fiber ring cavity laser source of claim 1, wherein the fiber-based gain medium is configured for amplified spontaneous emission based on a pump signal from the fiber-based pump laser.

3. The fiber ring cavity laser source of claim 2, wherein the fiber-based gain medium comprises a Fluoride.

4. The fiber ring cavity laser source of claim 2, wherein the fiber-based gain medium comprises a rare-earth doped Fluoride.

5. The fiber ring cavity laser source of claim 2, wherein the fiber-based gain medium comprises Praseodymium-doped Fluoride.

6. The fiber ring cavity laser source of claim 1, wherein the fiber-based gain medium is configured for generating an emission having a spectral range.

7. The fiber ring cavity laser source of claim 6, wherein the spectral range comprises visible light.

8. The fiber ring cavity laser source of claim 6, wherein the spectral range comprises blue to red visible light.

9. The fiber ring cavity laser source of claim 6, wherein the spectral range comprises near-infrared light.

10. The fiber ring cavity laser source of claim 6, wherein the spectral range comprises visible light and near-infrared light.

11. The fiber ring cavity laser source of claim 6, wherein the spectral range comprises blue to near-infrared light.

12. The fiber ring cavity laser source of claim 1, wherein the fiber-based reflector comprises a Fiber Bragg Grating.

13. The fiber ring cavity laser source of claim 12, comprising a tuning component for tensioning and/or compressing the Fiber Bragg Grating.

14. The fiber ring cavity laser source of claim 1, wherein at least the fiber-based circulator, the fiber-based coupler, and the fiber-based combiner are configured for an operation range of the laser output.

15. A tunable ring cavity laser source comprising:
a ring cavity structure;
a fiber-based circulator coupled in an optical path of the ring cavity structure;
a fiber-based reflector coupled to a fiber port of the circulator; and
a tuning component for the fiber-based reflector for tuning a wavelength of a laser output signal of the ring cavity laser source.

16. The tunable ring cavity laser source of claim 15, wherein the fiber-based reflector comprises a fiber Bragg grating.

17. The tunable ring cavity laser source of claim 16, wherein the tuning component is configured for tensioning and/or compressing the fiber Bragg grating for effecting the wavelength tuning.

18. A method of fabricating a ring cavity laser source, the method comprising the steps of:
coupling a first output fiber port of a fiber-based coupler to a first fiber port of a fiber-based circulator;
coupling an input fiber port of the fiber-based coupler to a first end of a fiber-based gain medium;
coupling a fiber-based reflector to a second port of the fiber-based circulator;
coupling a first input fiber port of a fiber-based combiner to the fiber pigtailed pump laser;
coupling a second input fiber port of the fiber-based combiner to a third port of the fiber-based circulator;
coupling an output fiber port of the fiber-based combiner to a second end of the fiber-based gain medium; and
configuring the fiber-based reflector for wavelength tuning of a laser output at a second output fiber port of the fiber-based coupler.

19. The method of claim 18, wherein the fiber-based reflector comprises a fiber Bragg grating.

20. The method of claim 19, comprising configuring the fiber Bragg grating for tensioning and/or compressing for effecting the wavelength tuning.
